(19) United States
(12) Patent Application Publication
(10) Pub. No.: US 2026/0362589 A1
(43) Pub. Date: Nov. 12, 2026

(54) FLEXIBLE CIRCUIT BOARD

(71) Applicant: CHIPBOND TECHNOLOGY CORPORATION, Hsinchu City (TW)

(72) Inventors: Kuei-Hao Pang, Kaohsiung City (TW); Ming-Hsun Wu, Kaohsiung City (TW); Ching-Fang Chen, Kaohsiung City (TW); Wan-Ting Fang, Kaohsiung City (TW); Pei-Yi Wang, Kaohsiung City (TW)

(21) Appl. No.: 19/276,235

(22) Filed: Jul. 22, 2025

(30) Foreign Application Priority Data
May 6, 2025 (TW) 114117009

(51) Int. Cl. H05K 1/02; H05K 1/14

(52) U.S. Cl. CPC H05K 1/0281; H05K 1/147; H05K 2201/09227; H05K 2201/09272; H05K 2201/095

(57) ABSTRACT

A flexible circuit board includes a substrate, a circuit layer and honeycomb lattice structures. The circuit layer is provided on a substrate unit portion of the substrate, the honeycomb lattice structures are provided on a warpage-resistant portion of the substrate. Each of the honeycomb lattice structures includes a first rib, a second rib, a third rib, a first honeycomb lattice space, a second honeycomb lattice space and a third honeycomb lattice space. The first, second and third ribs are connected at a point to become a radial supporting frame. The radial supporting frames of the adjacent honeycomb lattice structures are connected to avoid bending stress induced by material properties difference or environmental variation and maintain the size of the substrate unit portion.

### CROSS-REFERENCE TO RELATED APPLICATIONS

This application claims priority to R.O.C Patent Application No. 114117009 filed May 6, 2025, the disclosure of which is hereby incorporated by reference in its entirety.

### FIELD OF THE INVENTION

This invention relates to a flexible circuit board, and more particularly to a low-warpage flexible circuit board.

### BACKGROUND OF THE INVENTION

Conventional flexible circuit board tape involves multiple flexible circuit boards and it is usually rolled on a reel for some processes, e.g. chip bonding, testing or cutting process. Each of the flexible circuit boards includes a substrate, a circuit layer and a solder layer which are have different material properties, such as different coefficients of elasticity and thermal expansion. During rolling or transporting the flexible circuit board tape, the flexible circuit boards may be under pulling force to be bent or distorted.

If warpage occurs in the flexible circuit boards, inner leads of the circuit layer may not be bonded to a chip precisely, probe card may not precisely align test pads of the circuit layer for testing, the flexible circuit boards may not be cut precisely along a cutting line by a cutting tool, and circuit lines of the circuit layer may be damaged.

In order to avoid warpage, elongated patterns are usually provided on the flexible circuit boards in a direction perpendicular or parallel to rolling/transporting direction of the flexible circuit board tape. However, the flexible circuit boards may be bent or distorted at any position by forces from different directions, warpage may be still observed in the flexible circuit boards with the elongated patterns.

### SUMMARY OF THE INVENTION

One object of the present invention is to provide a low-warpage flexible circuit board which includes honeycomb lattice structures provided on a warpage-resistant portion of a substrate. Radial supporting frames of the honeycomb lattice structures are connected with each other to resist bending stress and avoid warpage.

A flexible circuit board of the present invention includes a substrate, a circuit layer and honeycomb lattice structures. The substrate includes a substrate unit portion, a warpage-resistant portion and a sprocket hole portion defined on a surface of the substrate, and the warpage-resistant portion is located between the substrate unit portion and the sprocket hole portion in a first direction. A chip mounting area, a first circuit area and a second circuit area are defined on the substrate unit portion, and the chip mounting area is located between the first and second circuit areas in a second direction intersecting the first direction. The circuit layer includes first circuit lines and second circuit lines. The first circuit lines are provided on the first circuit area and each has a first inner lead and a first outer lead. The second circuit lines are provided on the second circuit area and each has a second inner lead and a second outer lead. The first and second inner leads are arranged on the chip mounting area. The honeycomb lattice structures are provided on the warpage-resistant portion and each includes a first rib, a second rib, a third rib, a first honeycomb lattice space, a second honeycomb lattice space and a third honeycomb lattice space. The first, second and third ribs are connected at a point to become a radial supporting frame. In a circular direction around the point, the first rib is located between the first and second honeycomb lattice spaces which are adjacent, the second rib is located between the second and third honeycomb lattice spaces which are adjacent, and the third rib is located between the third and first honeycomb lattice spaces which are adjacent. A first included angle exists between the first and second ribs, a second included angle exists between the second and third ribs, and a third included angle exists between the third and first ribs. The radial supporting frames of the adjacent honeycomb lattice structures are connected with each other.

The radial supporting frames of the adjacent honeycomb lattice structures are connected with each other, as a result, the honeycomb lattice structures arranged on the warpage-resistant portion can resist bending stresses from different directions to avoid bending or distortion of the flexible circuit board and maintain the size of the substrate unit portion.

### BRIEF DESCRIPTION OF DRAWINGS

FIG. 1 is top view diagram illustrating a flexible circuit board tape in accordance with one embodiment of the present invention.

FIG. 2 is a top view diagram illustrating a part of a flexible circuit board in accordance with one embodiment of the present invention.

FIG. 3 is a top view diagram illustrating a part of a honeycomb lattice structure on a flexible circuit board in accordance with one embodiment of the present invention.

FIG. 4 is a cross-section view diagram illustrating a part of a flexible circuit board in accordance with one embodiment of the present invention.

FIG. 5 is a bottom view diagram illustrating a solder resist layer of a flexible circuit board in accordance with one embodiment of the present invention.

### DETAILED DESCRIPTION OF THE INVENTION

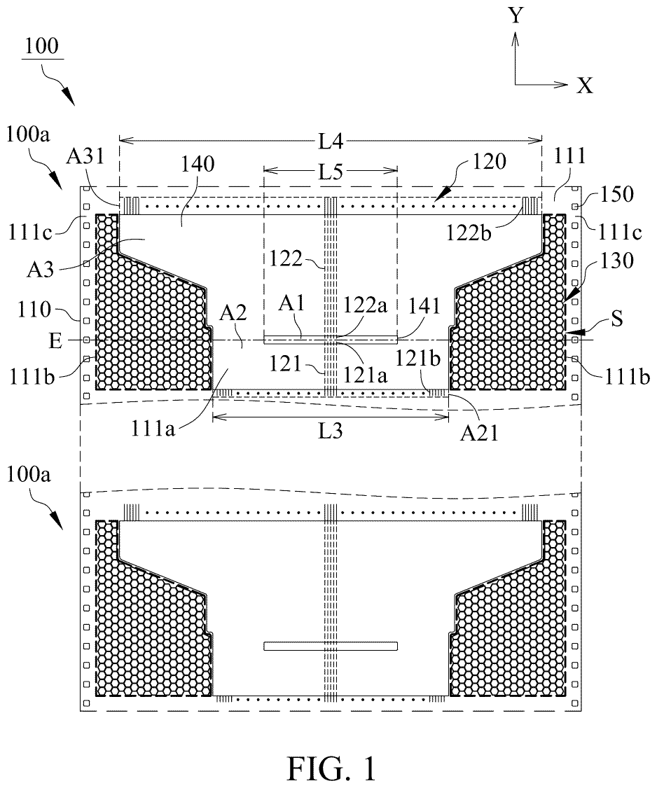

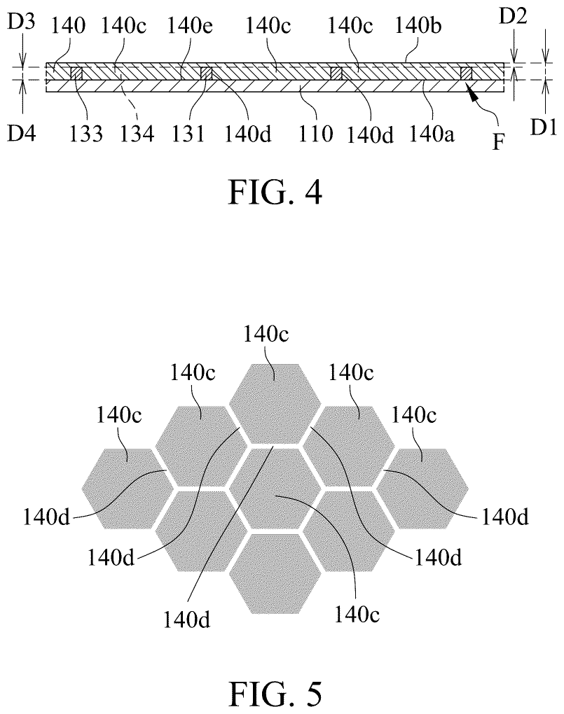

With reference to FIGS. 1 to 5, a flexible circuit board tape 100 in accordance with one embodiment of the present invention includes a plurality of flexible circuit boards 100a which are connected to one another. Each of the flexible circuit boards 100a includes a substrate 110, a circuit layer 120 and a plurality of honeycomb lattice structures 130. The substrate 110 may be made of polyimide (PI) or other flexible materials, and the circuit layer 120 may be made of copper or other metals. The circuit layer 120 and the honeycomb lattice structures 130 are provided on a surface 111 of the substrate 110, and preferably, each of the flexible circuit boards 100a further includes a solder resist layer 140 which covers the circuit layer 120 and the honeycomb lattice structures 130.

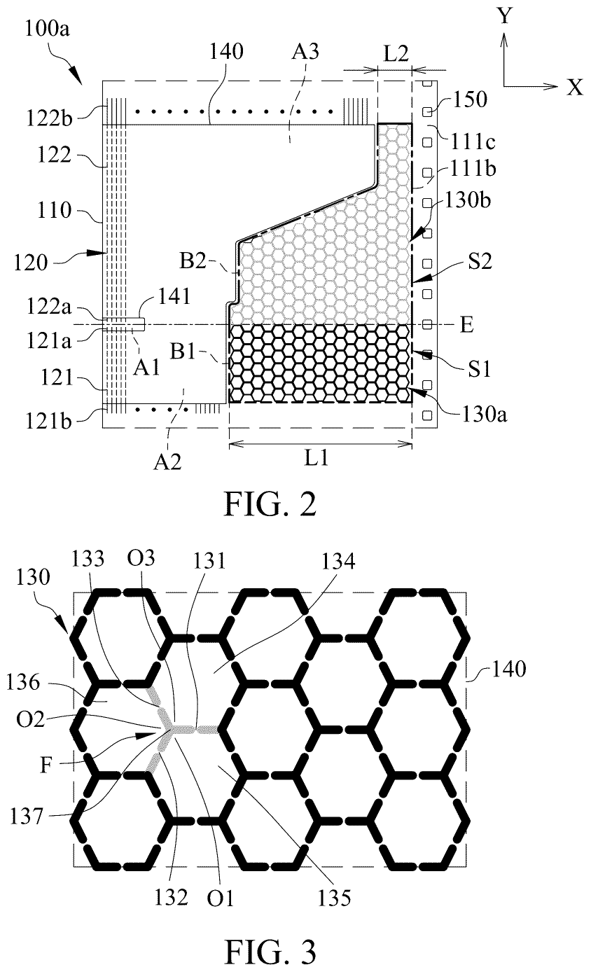

With reference to FIGS. 1 and 2, there are a substrate unit portion 111a, at least one warpage-resistant portion 111b and a sprocket hole portion 111c defined on the surface 111 of the substrate 110. Along a first direction X, the warpage-resistant portion 111b is located between the substrate unit portion 111a and the sprocket hole portion 111c, and in this embodiment, there are two warpage-resistant portions 111b defined on the surface 111, and the substrate unit portion 111a is located between the two warpage-resistant portions 111b. The circuit layer 120 is provided on the substrate unit portion 111a, the honeycomb lattice structures 130 are provided on the warpage-resistant portion 111b, and sprocket holes 150 are provided on the sprocket hole portion 111c. The sprocket holes 150 are arranged along a second direction Y which intersects the first direction X, and in this embodiment, the second direction Y is perpendicular to the first direction X and it is the direction for rolling or transporting the flexible circuit board tape 100.

With reference to FIGS. 1 and 2, the substrate unit portion 111a can be divided into a chip mounting area A1, a first circuit area A2 and a second circuit area A3. Along the second direction Y, the chip mounting area A1 is located between the first circuit area A2 and the second circuit area A3.

Referring to FIGS. 1 and 2, the circuit layer 120 includes first circuit lines 121 and second circuit lines 122. The first circuit lines 121 are provided on the first circuit area A2 and each has a first inner lead 121a and a first outer lead 121b. The second circuit lines 122 are provided on the second circuit area A3 and each has a second inner lead 122a and a second outer lead 122b. The first and second inner leads 121a and 122a are arranged on the chip mounting area A1 for bonding a chip (not shown). The first outer lead 121b is located on a first outer bonding region A21 within the first circuit area A2, and the second outer lead 122b is located on a second outer bonding region A31 within the second circuit area A3. A first maximum length L3 of the first outer bonding region A21 and a second maximum length L4 of the second outer bonding region A31 are defined in the first direction X, a quotient of the first maximum length L3 and the second maximum length L4 is greater than 0 and less than or equal to 0.8 (0<L3/L4≤0.8), and the second maximum length L4 is greater than or equal to 55 mm.

With reference to FIGS. 1 and 2, the solder resist layer 140 has an opening 141, and the chip mounting area A1, the first inner lead 121a and the second inner lead 122a are visible from the opening 141. A length L5 of the opening 141 is defined in the first direction X, a quotient of the length L5 and the second maximum length L4 of the second outer bonding region A31 is greater than 0 and less than or equal to 0.7 (0<L5/L4≤0.7), and the length L5 of the opening 141 is greater than or equal to 5 mm.

With reference to FIGS. 1 to 3, each of the honeycomb lattice structures 130 at least includes a first rib 131, a second rib 132, a third rib 133, a first honeycomb lattice space 134, a second honeycomb lattice space 135 and a third honeycomb lattice space 136. Preferably, the first, second and third honeycomb lattice spaces 134, 135 and 136 are hexagonal spaces. The first, second and third ribs 131, 132 and 133 are connected at a point 137 to become a radial supporting frame F. In a circular direction around the point 137, the first rib 131 is located between the first and second honeycomb lattice spaces 134 and 135 which are adjacent, the second rib 132 is located between the second and third honeycomb lattice spaces 135 and 136 which are adjacent, and the third rib 133 is located between the third and first honeycomb lattice spaces 136 and 134 which are adjacent. A first included angle O1 exists between the first and second ribs 131 and 132, a second included angle O2 exists between the second and third ribs 132 and 133, a third included angle O3 exists between the third and first ribs 133 and 131. In this embodiment, the first, second and third included angles O1, O2 and O3 are substantially equal, and the circular direction is clockwise direction. The radial supporting frames F of the adjacent honeycomb lattice structures 130 are connected with each other and used for dispersing bending stresses from different directions.

With reference to FIGS. 1 to 3, preferably, an area quotient of the warpage-resistant portion 111b covered by the first, second and third ribs 131, 132 and 133 and the warpage-resistant portion 111 b is greater than 0 and less than or equal to 0.5 (0<covered area/total area≤0.5), the honeycomb lattice structures 130 are arranged on a sub-area S within the warpage-resistant portion 111b, and an area quotient of the sub-area S and the warpage-resistant portion 111 b is greater than or equal to 0.2 and less than or equal to 1 (0.2 ≤S/111b≤1). The area of the solder resist layer 140 covering the radial supporting frames F can be increased, and the areas of the solder resist layer 140 filling in the first, second and third honeycomb spaces 134, 135 and 136 and adhering the surface 111 of the substrate 110 also can be increased. Accordingly, the warpage-resistant portion 111b is improved to disperse bending stresses from different directions and avoid stress concentration.

With reference to FIGS. 1 and 2, an imaginary dividing line E passes through a center of the chip mounting area A1 and extends to the warpage-resistant portion 111b in the first direction X. The warpage-resistant portion 111b is divided into a first warpage-resistant area B1 and a second warpage-resistant area B2 by the imaginary dividing line E. In the first direction X, the first warpage-resistant area B1 is located between the first circuit area A2 and the sprocket hole portion 111c, and the second warpage-resistant area B2 is located between the second circuit area A3 and the sprocket hole portion 111c. Preferably, there are a first honeycomb lattice structure 130a and a second honeycomb lattice structure 130b which are connected with each other. The first honeycomb lattice structure 130a is located on a first sub-area S1 within the first warpage-resistant area B1, and the second honeycomb lattice structure 130b is located on a second sub-area S2 within the second warpage-resistant area B2. An area quotient of the first sub-area S1 and the second sub-area S2 is greater than or equal to 0.1 and less than or equal to 1 (0.1≤S1/S2≤1).

With reference to FIG. 2, a maximum length L1 of the first sub-area S1 and a minimum length L2 of the second sub-area S2 are defined in the first direction. A quotient of the minimum length L2 of the second sub-area S2 and the maximum length L1 of the first sub-area S1 is greater than 0 and less than or equal to 1 (0<L2/L1≤1), and the maximum length L1 of the first sub-area S1 is greater than or equal to 10 mm. As a result, dispersing bending stresses from different directions is feasible to avoid stress concentration.

With reference to FIGS. 3 to 5, the solder resist layer 140 covers the radial supporting frames F and fills in the first, second and third honeycomb lattice spaces 134, 135 and 136. There are honeycomb lattice blocks 140c and grooves 140d formed on a bottom surface 140a of the solder resist layer 140, and each of the grooves 140d is located between the adjacent honeycomb lattice blocks 140c. In this embodiment, the honeycomb lattice blocks 140c are hexagonal blocks. Each of the first, second and third ribs 131, 132 and 133 are located in one of the grooves 140d. The solder resist layer 140 has a first thickness D1 from a top surface 140b of the solder resist layer 140 to a bottom surface 140e of the honeycomb lattice block 140c. The solder resist layer 140, which covers and is located on the first circuit lines 121, the second circuit lines 122 and the radial supporting frames F, has a second thickness D2 which is less than the first thickness D1. Each of the grooves 140d has a depth D3 which is equal to a thickness D4 of the circuit layer 120 and the first, second and third ribs 131, 132 and 133.

In order to avoid warpage of the flexible circuit boards 100a, the honeycomb lattice structures 130 of the present invention are provided on the warpage-resistant portion 111b to resist bending stresses from different directions caused by material properties difference or environmental variation. Furthermore, the solder resist layer 140 covers the honeycomb lattice structures 130 and fills in the first, second and third honeycomb lattice spaces 134, 135 and 136 to form the honeycomb lattice blocks 140c, the honeycomb lattice blocks 140c and the solder resist layer 140 covering the radial supporting frames F can improve resistance strength of the warpage-resistant portion 111b to disperse bending stresses from different directions and avoid stress concentration.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A flexible circuit board comprising:
a substrate including a substrate unit portion, a warpage-resistant portion and a sprocket hole portion defined on a surface of the substrate, the warpage-resistant portion is located between the substrate unit portion and the sprocket hole portion in a first direction, a chip mounting area, a first circuit area and a second circuit area are defined on the substrate unit portion, and the chip mounting area is located between the first and second circuit areas in a second direction intersecting the first direction;
a circuit layer including a plurality of first circuit lines and a plurality of second circuit lines, the plurality of first circuit lines are arranged on the first circuit area and each includes a first inner lead and a first outer lead, the plurality of second circuit lines are arranged on the second circuit area and each includes a second inner lead and a second outer lead, the first and second inner leads are arranged on the chip mounting area; and
a plurality of honeycomb lattice structures arranged on the warpage-resistant portion, each of the plurality of honeycomb lattice structures includes a first rib, a second rib, a third rib, a first honeycomb lattice space, a second honeycomb lattice space and a third honeycomb lattice space, the first, second and third ribs are connected at a point to become a radial supporting frame, in a circular direction around the point, the first rib is located between the first and second honeycomb lattice spaces which are adjacent, the second rib is located between the second and third honeycomb lattice spaces which are adjacent, and the third rib is located between the third and first honeycomb lattice spaces which are adjacent, an first included angle exists between the first and second ribs, a second included angle exists between the second and third ribs, and a third included angle exists between the third and first ribs, wherein the radial supporting frames of the adjacent honeycomb lattice structures are connected with each other.

2. The flexible circuit board in accordance with claim 1, wherein an area quotient of the warpage-resistant portion covered by the first, second and third ribs of the plurality of honeycomb lattice structures and the warpage-resistant portion is less than or equal to 0.5.

3. The flexible circuit board in accordance with claim 1, wherein the plurality of honeycomb lattice structures are arranged on a sub-area within the warpage-resistant portion, and an area quotient of the sub-area and the warpage-resistant portion is greater than or equal to 0.2.

4. The flexible circuit board in accordance with claim 1, wherein the warpage-resistant portion is divided into a first warpage-resistant area and a second warpage-resistant area by an imaginary dividing line which passes through a center of the chip mounting area and extends to the warpage-resistant portion in the first direction, the first warpage-resistant area is located between the first circuit area and the sprocket hole portion in the first direction, the second warpage-resistant area is located between the second circuit area and the sprocket hole portion in the first direction, there are a first honeycomb lattice structure and a second honeycomb lattice structure, the first honeycomb lattice structure is located on a first sub-area within the first warpage-resistant area, the second honeycomb lattice structure is located on a second sub-area within the second warpage-resistant area, and an area quotient of the first and second sub-areas is greater than or equal to 0.1 and less than or equal to 1.

5. The flexible circuit board in accordance with claim 4, wherein the first sub-area has a maximum length and the second sub-area has a minimum length in the first direction, a quotient of the minimum length of the second sub-area and the maximum length of the first sub-area is less than or equal to 1, and the maximum length of the first sub-area is less than or equal to 10 mm.

6. The flexible circuit board in accordance with claim 4, wherein the first honeycomb lattice structure is connected to the second honeycomb lattice structure.

7. The flexible circuit board in accordance with claim 2, wherein the warpage-resistant portion is divided into a first warpage-resistant area and a second warpage-resistant area by an imaginary dividing line which passes through a center of the chip mounting area and extends to the warpage-resistant portion in the first direction, the first warpage-resistant area is located between the first circuit area and the sprocket hole portion in the first direction, the second warpage-resistant area is located between the second circuit area and the sprocket hole portion in the first direction, there are a first honeycomb lattice structure and a second honeycomb lattice structure, the first honeycomb lattice structure is located on a first sub-area within the first warpage-resistant area, the second honeycomb lattice structure is located on a second sub-area within the second warpage-resistant area, and an area quotient of the first and second sub-areas is greater than or equal to 0.1 and less than or equal to 1.

8. The flexible circuit board in accordance with claim 7, wherein the first sub-area has a maximum length and the second sub-area has a minimum length in the first direction, a quotient of the minimum length of the second sub-area and the maximum length of the first sub-area is less than or equal to 1, and the maximum length of the first sub-area is less than or equal to 10 mm.

9. The flexible circuit board in accordance with claim 7, wherein the first honeycomb lattice structure is connected to the second honeycomb lattice structure.

10. The flexible circuit board in accordance with claim 3, wherein the warpage-resistant portion is divided into a first warpage-resistant area and a second warpage-resistant area by an imaginary dividing line which passes through a center of the chip mounting area and extends to the warpage-resistant portion in the first direction, the first warpage-resistant area is located between the first circuit area and the sprocket hole portion in the first direction, the second warpage-resistant area is located between the second circuit area and the sprocket hole portion in the first direction, there are a first honeycomb lattice structure and a second honeycomb lattice structure, the first honeycomb lattice structure is located on a first sub-area within the first warpage-resistant area, the second honeycomb lattice structure is located on a second sub-area within the second warpage-resistant area, and an area quotient of the first and second sub-areas is greater than or equal to 0.1 and less than or equal to 1.

11. The flexible circuit board in accordance with claim 10, wherein the first sub-area has a maximum length and the second sub-area has a minimum length in the first direction, a quotient of the minimum length of the second sub-area and the maximum length of the first sub-area is less than or equal to 1, and the maximum length of the first sub-area is less than or equal to 10 mm.

12. The flexible circuit board in accordance with claim 10, wherein the first honeycomb lattice structure is connected to the second honeycomb lattice structure.

13. The flexible circuit board in accordance with claim 1, wherein the first outer lead is arranged on a first outer bonding region within the first circuit area, the second outer lead is arranged on a second outer bonding region within the second circuit area, the first outer bonding region has a first maximum length and the second outer bonding region has a second maximum length in the first direction, a quotient of the first and second maximum lengths is less than or equal to 0.8, and the second maximum length of the second outer bonding region is greater than or equal to 55 mm.

14. The flexible circuit board in accordance with claim 13 further comprising a solder resist layer, wherein the solder resist layer covers the circuit layer and has an opening, the chip mounting area, the first and second inner leads are visible from the opening, the opening has a length greater than or equal to 5 mm in the first direction, a quotient of the length of the opening and the second maximum length of the second outer bonding region is less than or equal to 0.7.

15. The flexible circuit board in accordance with claim 1 further comprising a solder resist layer, wherein the solder resist layer covers the radial supporting frame of each of the plurality of honeycomb lattice structures and fills in the first, second and third honeycomb lattice spaces, there are a plurality honeycomb lattice blocks and a plurality of grooves on a bottom surface of the solder resist layer, each of the plurality of grooves is located between the adjacent honeycomb lattice blocks.

16. The flexible circuit board in accordance with claim 15, wherein the solder resist layer has a first thickness from a top surface of the solder resist layer to a bottom surface of each of the plurality of honeycomb lattice blocks, and the solder resist layer covering and located on the radial supporting frame has a second thickness which is less than the first thickness.

17. The flexible circuit board in accordance with claim 16, wherein each of the plurality of grooves has a depth which is equal to a thickness of the circuit layer.

18. The flexible circuit board in accordance with claim 1, wherein the first included angle is equal to the second included angle.
